(19) United States
(12) Patent Application Publication
(10) Pub. No.: US 2026/0087192 A1
(43) Pub. Date: Mar. 26, 2026

(54) VEHICLE COOLING FLOW SIMULATION METHODS

(71) Applicant: FCA US LLC, Auburn Hills, MI (US)

(72) Inventors: Venkata Krishna Mohan Chagarlamudi, Auburn Hills, MI (US); Sreekanth Surapaneni, Auburn Hills, MI (US); Uday Kiran Mahakali, Auburn Hills, MI (US)

(21) Appl. No.: 18/893,271

(22) Filed: Sep. 23, 2024

(51) Int. Cl. G06F 30/15; G06F 30/27; G06F 30/28

(52) U.S. Cl. CPC G06F 30/15; G06F 30/27; G06F 30/28

(57) ABSTRACT

A system for automated design of a vehicle front end thermal system having one or more heat exchangers configured to provide cooling to a vehicle torque generating device includes a trained artificial intelligence (AI) model based on a comprehensive computational fluid dynamics (CFD) database. A computing device is configured to receive CAD data defining a vehicle front end environment, predict, with the trained AI model, an airflow through the one or more heat exchangers, determine if the predicted airflow meets or exceeds a predetermined airflow target configured to remove a predetermined amount of thermal energy from the one or more heat exchangers, provide, via the trained AI model, AI driven design changes to the CAD data, provide final CAD data of an optimized design achieved using the trained AI model, and perform a CFD simulation of the final CAD data to validate the optimized design.

### FIELD

The present application generally relates to vehicle thermal system simulation techniques and, more particularly, to a system and method for simulating vehicle cooling flow with artificial intelligence.

### BACKGROUND

Computational fluid dynamics (CFD) is an iterative process that may be utilized to simulate coolant flows in vehicle thermal systems. The CFD tool calculates the flow through vehicle heat exchangers and determines if the calculated flow is enough to dissipate generated heat to the coolant to maintain optimal engine temperature and prevent overheating. However, the process is often labor intensive and can require preprocessing steps like CAD cleanup and meshing that is time consuming. Moreover, the CFD tools frequently require high-performance computational capability to provide results in a timely manner. As such, conventional systems have high labor and computational costs. Accordingly, while such conventional processes work well for their intended purpose, there exists an opportunity for improvement in the relevant art.

### SUMMARY

According to one example aspect of the invention, a system for automated design of a vehicle front end thermal system having one or more heat exchangers configured to provide cooling to a vehicle torque generating device is provided. In one example implementation, the system includes a trained artificial intelligence (AI) model based on a comprehensive computational fluid dynamics (CFD) database, and a computing device, including one or more processors and a non-transitory computer-readable storge medium having a plurality of instructions thereon, which, when executed by the one or more processors, cause the one or more processors to perform the following operations. Receiving CAD data defining a vehicle front end environment including the thermal system; predicting, with the trained AI model, an airflow through the one or more heat exchangers; determining if the predicted airflow meets or exceeds a predetermined airflow target configured to remove a predetermined amount of thermal energy from the one or more heat exchangers to cool and maintain the torque generating device at a predetermined temperature; providing, via the trained AI model, AI driven design changes to the CAD data if the predicted airflow does not meet the predetermined airflow target; providing final CAD data of an optimized design achieved using the trained AI model, if the predicted airflow meets or exceeds the predetermined airflow target; and performing a CFD simulation of the final CAD data to validate the optimized design achieved using the trained AI model.

In addition to the foregoing, the described system may include one or more of the following features: wherein the one or more processors further provide the final CAD data to the CFD database and/or the trained AI model to update and further train the AI model; wherein predicting the airflow includes determining a pressure drop across the one or more heat exchangers, and subsequently converting the determined pressure drop into the predicted airflow; wherein the trained AI model is configured for machine learning using one or more algorithms and statistical models to enable the trained AI model to learn from and make predictions or decisions based on data; and wherein the trained AI model utilizes a convolutional neural network (CNN), a recurrent neural network (RNN), and a generative adversarial network (GAN).

In addition to the foregoing, the described system may include one or more of the following features: wherein the CFD simulation database is a dataset of a plurality of CFD simulations of vehicle thermal systems; wherein the AI driven design changes include changes to front end grille openings, changes to sealing, changes to a fan setup, and changes to a stacking of the one or more heat exchangers; wherein the thermal system includes a high temperature circuit, a low temperature circuit, and an air conditioning circuit; and wherein the one or more heat exchangers includes all of a first radiator disposed on the high temperature circuit, a second radiator disposed on the low temperature circuit, and a condenser disposed on the air conditioning circuit.

According to another example aspect of the invention, a computer-implemented method of designing a vehicle front end thermal system having one or more heat exchangers configured to provide cooling to a vehicle torque generating device is provided. In one example implementation, the method includes receiving, by a computing device having one or more processors, CAD data defining a vehicle front end environment including the thermal system; predicting, with a trained artificial intelligence (AI) model based on a comprehensive computational fluid dynamics (CFD) database, an airflow through the one or more heat exchangers; determining if the predicted airflow meets or exceeds a predetermined airflow target configured to remove a predetermined amount of thermal energy from the one or more heat exchangers to cool and maintain the torque generating device at a predetermined temperature; providing, via the trained AI model, AI driven design changes to the CAD data if the predicted airflow does not meet the predetermined airflow target; providing final CAD data of an optimized design achieved using the trained AI model, if the predicted airflow meets or exceeds the predetermined airflow target; and performing a CFD simulation of the final CAD data to validate the optimized design achieved using the trained AI model.

In addition to the foregoing, the described method may include one or more of the following features: providing the final CAD data to the CFD database and/or the trained AI model to update and further train the AI model; wherein predicting the airflow includes determining a pressure drop across the one or more heat exchangers, and subsequently converting the determined pressure drop into the predicted airflow; wherein the trained AI model is configured for machine learning using one or more algorithms and statistical models to enable the trained AI model to learn from and make predictions or decisions based on data; and wherein the trained AI model utilizes one or more of a convolutional neural network (CNN), a recurrent neural network (RNN), and a generative adversarial network (GAN).

In addition to the foregoing, the described method may include one or more of the following features: wherein the CFD simulation database is a dataset of a plurality of CFD simulations of vehicle thermal systems; wherein the AI driven design changes include changes to front end grille openings, changes to sealing, changes to a fan setup, and changes to a stacking of the one or more heat exchangers; wherein the thermal system includes a high temperature circuit, a low temperature circuit, and an air conditioning circuit; and wherein the one or more heat exchangers includes all of a first radiator disposed on the high temperature circuit, a second radiator disposed on the low temperature circuit, and a condenser disposed on the air conditioning circuit.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a schematic view of an example vehicle system in accordance with the principles of the present disclosure; and

FIG. 2 is a flow diagram illustrating an example computer-implemented method of designing a vehicle front end thermal system, in accordance with the principles of the present disclosure.

### DESCRIPTION

As discussed above, computational fluid dynamics (CFD) simulations of vehicle thermal systems are labor intensive and time consuming. Preprocessing steps like CAD cleanup and meshing requires many hours to prepare the CFD model. The mesh count for such models may be in the range of sixty million for a full vehicle model. Moreover, the CFD tools that handle the simulations require high-performance computational capability to provide the results in a timely manner.

Accordingly, the present disclosure provides a system and techniques for performing CFD simulations with a trained artificial intelligence (AI) model. In one example, the trained AI model utilizes machine learning (ML) to complement the CFD simulation capabilities. Physics-informed (physics driven) and physics-agnostic (data driven) methods are used to train the AI models. The trained AI model runs iterative studies and carries out design changes to arrive at a final system design. The final system designs are then sent to the CFD simulations only to confirm the optimum performance.

Physics-Informed Neural Networks (PINNs) integrate physics laws into the training process of neural networks. By incorporating governing equations directly into the neural network's loss function, PINNs ensure that the model's prediction adhere to known physical principles, leading to more accurate and reliable solutions. ML models utilize algorithms for supervised learning, unsupervised learning, and reinforced learning techniques to train the AI models. Deep learning neural networks (DNNs), which includes convolutional neural networks (CNNs) and recurrent neural networks (RNNs) are used to model complex relationships in simulation data. Transfer learning, a process by which pre-trained AI models with past simulation data predict the behavior of new designs, is utilized to apply knowledge gained from one simulation scenario to other related scenarios. This technique reduces the amount of training data and computational resources needed for new simulations by reusing pre-trained models.

Accordingly, the systems and methods described herein advantageously provide quick turn-around and iterations to drive design changes. The up front and preliminary AI iterations to drive design changes require less time and cost. Because CFD simulations are only run for confirmation, the need for high performance computing and high-cost model preparation and cleanup are eliminated. Additionally, the transfer learning ensures availability of pre-trained models to reduce the time required to build a database. As such, multi-variable optimization studies to handle front end openings, grille texture, fan speed/performance, and heat exchanger stacking and configuration can be handled with limited effort and pre-trained models.

In one example, the CNNs are a class of deep neural networks, commonly applied to analyzing visual imagery. They are designed to automatically and adaptively learn spatial hierarchies of features from input images. The RNNs are a class of artificial neural networks where connections between nodes form a directed graph along a temporal sequence. This allows them to exhibit temporal dynamic behavior, making them suitable for tasks involving sequential data like time series analysis or natural language processing. GANs include two neural networks, a generator and a discriminator, that contest each other in a zero-sum game framework. The generator creates fake data samples, while the discriminator attempts to distinguish between real and fake data samples. Such networks are particularly effective for realistic images and other types of data.

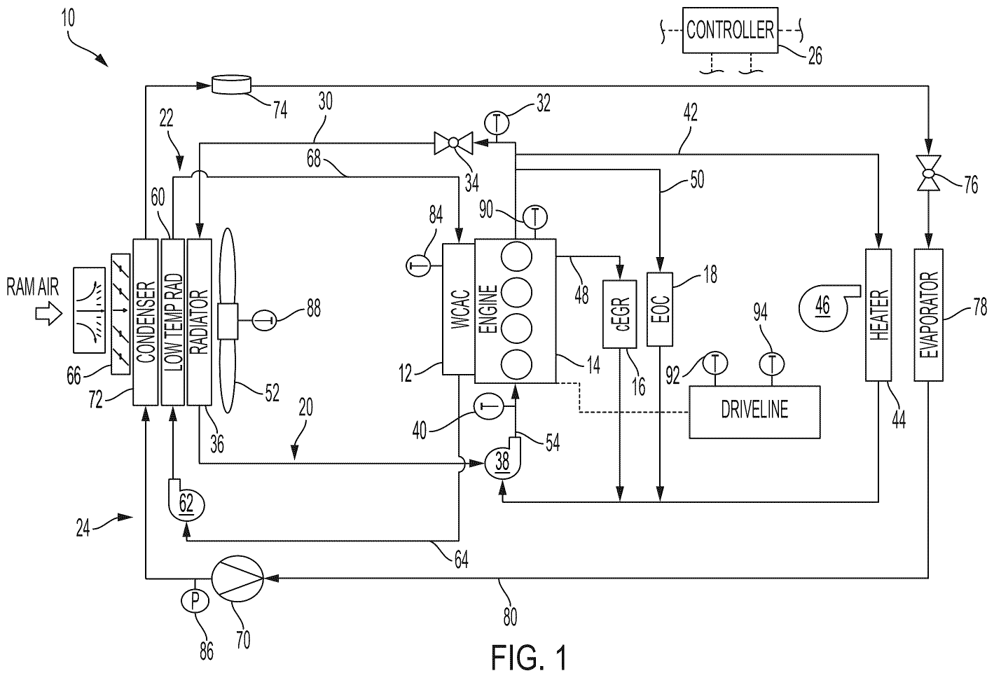

With initial reference to FIG. 1, an example vehicle thermal system is illustrated and generally identified at reference numeral 10. The thermal system 10 is configured to provide cooling to various components of the vehicle such as an intercooler 12, a vehicle engine 14, an exhaust gas recirculation (EGR) cooler 16, and an engine oil cooler 18. The intercooler 12 receives hot compressed air from a charger (not shown), absorbs heat therefrom, and subsequently supplies cooled, compressed air to an intake and cylinders (not shown) of the engine 14. It will be appreciated that thermal system 10 is only one example and thermal system 10 may have various configurations, for example, to accommodate another torque generating device such as, for example, an electric traction motor (instead of or in addition to engine 14).

In one exemplary implementation, the thermal system 10 generally includes a high temperature circuit 20, a low temperature circuit 22, and an air conditioning circuit 24. In one exemplary implementation, the circuits 20, 22, 24 are discrete circuits fluidly separate from each other. The thermal system 10 is in signal communication with a controller 26 such as an engine control unit (ECU), which is in signal communication with various components and sensors.

With continued reference to FIG. 1, in one exemplary implementation, the high temperature circuit 20 circulates a first heat transfer fluid or coolant (e.g., water) and generally includes a main circuit 30 having a temperature sensor or thermostat 32, a coolant control valve 34, a high temperature radiator 36, a pump 38, a second temperature sensor 40. A first branch circuit 42 includes a cabin heat exchanger 44 operably associated with a blower 46. A second branch circuit 48 includes EGR cooler 16, and a third branch circuit 50 includes engine oil cooler 18. The first coolant is heated by engine 14 and is subsequently supplied to main circuit 30, first branch circuit 42, second branch circuit 48, and third branch circuit 50.

The main circuit 30 directs heated coolant to the high temperature radiator 36, where the heated coolant is cooled by ambient air and/or an air flow created by a fan 52. Coolant control valve 34 is configured to vary the amount of flow of the first coolant through the high temperature circuit. The cooled first coolant is then supplied to a coolant supply line 54.

The first branch circuit 42 directs the heated coolant to the cabin heat exchanger 44 where thermal energy of the heated coolant is used to provide heating to the vehicle passenger cabin (not shown). The heated coolant is cooled by ambient air and/or an air flow created by blower 46, and the cooled coolant is then directed to the coolant supply line 54.

The second branch circuit 48 directs the heated coolant to the EGR cooler 16 where thermal energy of the EGR gas flow is transferred to the coolant via indirect thermal contact within the heat exchanger 16. The third branch circuit 50 directs the heated coolant to the engine oil cooler 18 where thermal energy of the engine oil is transferred to the coolant via indirect thermal contact within the heat exchanger 18.

The pump 38 is disposed within circuit 20 and is configured to circulate the first coolant around the high temperature circuit 20. In the example embodiment, the first coolant may be selectively supplied to branch circuits 42, 48, 50 such that each of the branch circuits may be used alone or in any combination. As such, pump 38 supplies the cooled coolant within supply line 54 to the engine 14 to provide cooling thereto.

In one exemplary implementation, the low temperature circuit 22 is fluidly separate from high temperature circuit 20 and circulates a second heat transfer fluid or coolant such as water. In the illustrated example, the low temperature circuit 22 is dedicated to providing cooling to only the intercooler 12. Low temperature circuit 22 generally includes a low temperature radiator 60 and a pump 62. The second coolant is heated within intercooler 12 against the hot compressed air from the charger, and is directed to low temperature radiator 60 via a conduit 64.

The heated second coolant is cooled within the low temperature radiator 60 by ambient air and/or ram airflow from fan 50. As used herein, ram airflow is the amount of ambient air forcing through a vehicle grille, such as an active grille shutter (AGS) 66, and heat exchange from dynamic air pressure created when the vehicle is in motion. Pump 62 is disposed within circuit 22 and is configured to circulate the second coolant around the low temperature circuit 22. As such, pump 62 supplies the cooled coolant from radiator 60 to coolant supply line 68.

With continued reference to FIG. 1, in one exemplary implementation, air conditioning circuit 24 is a standard vehicle air conditioning system that generally includes a compressor 70, a condenser 72, a receiver/dryer 74, an expansion device 76, and an evaporator 78.

In operation, a suction line 80 provides gaseous refrigerant to compressor 70, which subsequently compresses the refrigerant. The compressed and heated refrigerant is directed to the condenser 72 where the heat from compression is dissipated and the refrigerant condenses to a liquid. The liquid refrigerant is directed through expansion device 76 (e.g., an expansion valve) where it is reduced in pressure and vaporized, thereby reducing the temperature of the refrigerant. The cooled vapor refrigerant is then supplied to evaporator 78 where it is evaporated to providing cooling to the cabin air. The resulting gaseous, warmed refrigerant is then returned to the compressor 70 via suction line 80 where the cycle is repeated.

In the example embodiment, engine 14 is coupled to a driveline 82, which includes both transmission oil and axle oil that is heated by the engine coolant, thereby reducing the transmission and axle torque loss or increases the transmission and axle efficiency by reducing the oil viscosity.

System 10 also includes a plurality of sensors such as, for example, temperature sensors 32 and 40, an air charge temperature sensor 84, an AC circuit pressure sensor 86, a fan temperature sensor 88, an engine oil temperature sensor 88, an engine oil temperature sensor 90, a transmission oil temperature sensor 92, and an axle oil temperature sensor 94.

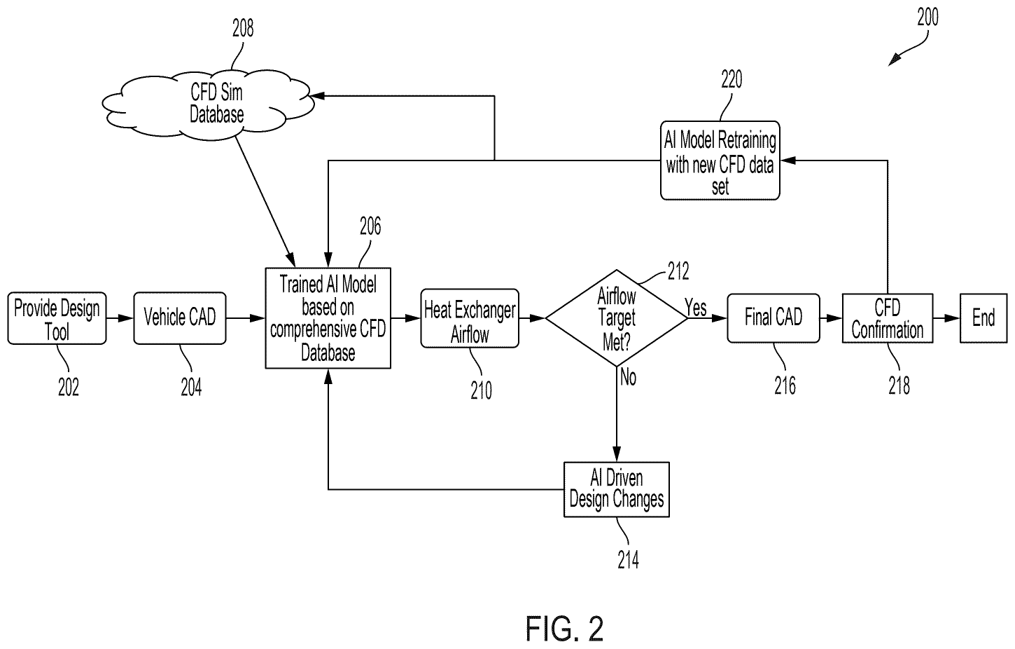

Referring now to FIG. 2, a flow diagram of an example computer implemented method 200 of designing a vehicle front end thermal system is provided. The method is configured to assist designing a front end thermal system to ensure sufficient airflow to various heat exchangers of the thermal system, to thereby provide a desired cooling to the engine and/or electric motor and one or more associated components (e.g., heat exchangers). While the components of vehicle thermal system 10 and FIG. 1 are referenced for explanatory purposes, it will be appreciated that this method 200 could be applicable to any suitable vehicle. The method begins at 202, where a design tool (e.g., a computer or controller) is provided. The design tool includes a trained AI model configured for machine learning using algorithms and statistical models to enable the design tool to learn from and make predictions or decisions based on data. The trained AI model may use one or more neural networks (e.g., CNN, RNN, GAN, PINN).

At 204, the design tool is provided with vehicle CAD data representing a vehicle environment to be designed/analyzed, such as the thermal system 10 and a front end of the vehicle (e.g., AGS 66). At 206, the vehicle CAD is provided to the trained AI model of the design tool. The trained AI model is based on a comprehensive CFD simulation database 208. The CFD simulation database 208 may be a dataset of a predetermined number of CFD simulations and may be updated on a regular basis for comprehensiveness and to allow for the continuous training of the AI model. The databases are designed based on morphed geometries and preselected design variations that allow AI to explore and effectively learn the full design space.

At 210, the trained AI model determines a heat exchanger airflow through the thermal system 10 environment based on the CAD data. This cooling airflow is based on a pressure drop across the heat exchangers, which is a parameter/variable very specific to the cooling flow application. Accordingly, in one example, this determined heat exchanger airflow is calculated by determining a pressure drop across one or more of the heat exchangers such as, for example, charge air cooler 12, EGR cooler 16, oil cooler 18, radiator 36, heater 44, radiator 60, condenser 72, and/or evaporator 78. The determined pressure drop is then converted into a predicted airflow (e.g., cfs) over each heat exchanger based on an experiment-based curve fit between pressure drop and corresponding airflow through that particular heat exchanger.

At 212, the design tool determines if the predicted airflow meets or exceeds a predetermined airflow target. In one example, the predetermined airflow target represents an airflow required to remove a predetermined amount of thermal energy from the coolant in thermal system 10 to maintain a predetermined desired temperature of a vehicle component (e.g., engine 14).

If the predicted airflow does not meet the airflow target, the method proceeds to step 214 and the trained AI model provides AI driven design changes to the CAD data. Such AI suggested iterative design changes to the CAD will be reevaluated without CFD intervention (e.g., pure AI driven design predictions). Example AI suggested design changes include changes to front end openings (e.g., grille, AGS 66), cooling module sealing that retains and guides the airflow to the heat exchangers, fan setup (e.g., location/size/calibration of radiator fan 52), and stacking of heat exchangers (e.g., 36, 60, 72). The method then returns to 206 to implement the design changes.

If the predicted airflow meets or exceeds the airflow target, the method proceeds to step 216 and provides final CAD data for a final version of the CAD that is ready for validation. At 218, the design tool performs a final CFD simulation of the final CAD data to validate the optimized design achieved using the trained AI model. Optionally, at 220, the final CFD simulation data may then be sent to the CFD simulation database 208 and/or the trained AI model to update/further train the AI model with the new data/information as it becomes available. The method then ends or returns to 202 for one or more iterations or new configuration of vehicle study.

It will be appreciated that the terms “controller” or “control system” or “module” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It will be understood that the mixing and matching of features, elements, methodologies, systems and/or functions between various examples may be expressly contemplated herein so that one skilled in the art will appreciate from the present teachings that features, elements, systems and/or functions of one example may be incorporated into another example as appropriate, unless described otherwise above. It will also be understood that the description, including disclosed examples and drawings, is merely exemplary in nature intended for purposes of illustration only and is not intended to limit the scope of the present application, its application or uses. Thus, variations that do not depart from the gist of the present application are intended to be within the scope of the present application.

What is claimed is:

1. A system for automated design of a vehicle front end thermal system having one or more heat exchangers configured to provide cooling to a vehicle torque generating device, the system comprising:
a trained artificial intelligence (AI) model based on a comprehensive computational fluid dynamics (CFD) database; and
a computing device, including one or more processors and a non-transitory computer-readable storge medium having a plurality of instructions thereon, which, when executed by the one or more processors, cause the one or more processors to perform operations comprising:
receiving CAD data defining a vehicle front end environment including the thermal system;
predicting, with the trained AI model, an airflow through the one or more heat exchangers;
determining if the predicted airflow meets or exceeds a predetermined airflow target configured to remove a predetermined amount of thermal energy from the one or more heat exchangers to cool and maintain the torque generating device at a predetermined temperature;
providing, via the trained AI model, AI driven design changes to the CAD data if the predicted airflow does not meet the predetermined airflow target;
providing final CAD data of an optimized design achieved using the trained AI model, if the predicted airflow meets or exceeds the predetermined airflow target; and
performing a CFD simulation of the final CAD data to validate the optimized design achieved using the trained AI model.

2. The system of claim 1, wherein the one or more processors further:
provide the final CAD data to the CFD database and/or the trained AI model to update and further train the AI model.

3. The system of claim 1, wherein predicting the airflow includes determining a pressure drop across the one or more heat exchangers, and subsequently converting the determined pressure drop into the predicted airflow.

4. The system of claim 1, wherein the trained AI model is configured for machine learning using one or more algorithms and statistical models to enable the trained AI model to learn from and make predictions or decisions based on data.

5. The system of claim 4, wherein the trained AI model utilizes the following:
a convolutional neural network (CNN);
a recurrent neural network (RNN); and
a generative adversarial network (GAN).

6. The system of claim 1, wherein the CFD simulation database is a dataset of a plurality of CFD simulations of vehicle thermal systems.

7. The system of claim 1, wherein the AI driven design changes comprise:
changes to front end grille openings;
changes to sealing;
changes to a fan setup; and
changes to a stacking of the one or more heat exchangers.

8. The system of claim 1, wherein the thermal system comprises:
a high temperature circuit;
a low temperature circuit; and
an air conditioning circuit;

9. The system of claim 8, wherein the one or more heat exchangers includes all of the following:
a first radiator disposed on the high temperature circuit;
a second radiator disposed on the low temperature circuit; and
a condenser disposed on the air conditioning circuit.

10. A computer-implemented method of designing a vehicle front end thermal system having one or more heat exchangers configured to provide cooling to a vehicle torque generating device, the method comprising:
receiving, by a computing device having one or more processors, CAD data defining a vehicle front end environment including the thermal system;
predicting, with a trained artificial intelligence (AI) model based on a comprehensive computational fluid dynamics (CFD) database, an airflow through the one or more heat exchangers;
determining if the predicted airflow meets or exceeds a predetermined airflow target configured to remove a predetermined amount of thermal energy from the one or more heat exchangers to cool and maintain the torque generating device at a predetermined temperature;
providing, via the trained AI model, AI driven design changes to the CAD data if the predicted airflow does not meet the predetermined airflow target;
providing final CAD data of an optimized design achieved using the trained AI model, if the predicted airflow meets or exceeds the predetermined airflow target; and
performing a CFD simulation of the final CAD data to validate the optimized design achieved using the trained AI model.

11. The method of claim 10, further comprising:
providing the final CAD data to the CFD database and/or the trained AI model to update and further train the AI model.

12. The method of claim 10, wherein predicting the airflow includes determining a pressure drop across the one or more heat exchangers, and subsequently converting the determined pressure drop into the predicted airflow.

13. The method of claim 10, wherein the trained AI model is configured for machine learning using one or more algorithms and statistical models to enable the trained AI model to learn from and make predictions or decisions based on data.

14. The method of claim 13, wherein the trained AI model utilizes one or more of the following:
a convolutional neural network (CNN);
a recurrent neural network (RNN); and
a generative adversarial network (GAN).

15. The method of claim 10, wherein the CFD simulation database is a dataset of a plurality of CFD simulations of vehicle thermal systems.

16. The method of claim 10, wherein the AI driven design changes comprise:
changes to front end grille openings;
changes to sealing;
changes to a fan setup; and
changes to a stacking of the one or more heat exchangers.

17. The method of claim 10, wherein the thermal system comprises:
a high temperature circuit;
a low temperature circuit; and
an air conditioning circuit;

18. The method of claim 17, wherein the one or more heat exchangers includes all of the following:
a first radiator disposed on the high temperature circuit;
a second radiator disposed on the low temperature circuit; and
a condenser disposed on the air conditioning circuit.
